(19) United States
(12) Patent Application Publication
(10) Pub. No.: US 2022/0404704 A1
(43) Pub. Date: Dec. 22, 2022

(54) METHOD FOR MANUFACTURING RESIN ASYMMETRICAL STRUCTURES

(71) Applicant: COMMISSARIAT A L'ENERGIE ATOMIQUE ET AUX ENERGIES ALTERNATIVES, Paris (FR)

(72) Inventors: Stefan LANDIS, Grenoble (FR); Romain LAURENT, Grenoble (FR)

(73) Assignee: COMMISSARIAT A L'ENERGIE ATOMIQUE ET AUX ENERGIES ALTERNATIVES, Paris (FR)

(21) Appl. No.: 17/638,688

(22) PCT Filed: Aug. 27, 2020
(86) PCT No.: PCT/EP2020/074030

§ 371 Date: Feb. 25, 2022

(30) Foreign Application Priority Data
Aug. 29, 2019 (FR) FR1909527

(51) Int. Cl. G03F 7/095; G03F 7/20

(52) U.S. Cl. CPC G03F 7/095; G03F 7/2022; G03F 7/70466

(57) ABSTRACT

A method for making at least one structure having sidewalls with different inclinations includes providing a stack including a substrate having a layer of a positive resin whose tone could be reversed when exposed to an insolation dose D<Dinversion, the patterns exposed to the dose Dinversion not being sensitive to creeping at the glass-transition temperature Tfluage of the resin; forming a non-sensitive first pattern by exposing the resin to a first dose D1≥Dinversion, the first pattern having a first sidewall having a first inclination; and forming a creep-sensitive second pattern by exposing the resin to a second dose D2<Dinversion. Creeping is performed by applying a temperature T≥Tfluage to make the second pattern creep over a portion of the first pattern by leaving uncovered at least partially the first sidewall of the first pattern, and defining at least one second sidewall having a second inclination different from the first inclination.

### TECHNICAL FIELD

The invention relates to the field of making asymmetrical structure i.e. structure having sidewalls whose inclinations are not identical over the entire contour of the structure. More particularly, it relates to making of such a structure in resin.

For example, the invention finds an advantageous application in diffraction gratings applied in particular to the display or optoelectronics fields.

### PRIOR ART

For many applications, for example in the display or optronics fields, it is advantageous to make structures whose sidewalls have one or several asymmetrical inclination(s).

When these patterns are one-dimensional (the sidewalls have a continuous inclination extending from the substrate to the top of the pattern) and they are organised in a network, they then form a network referred to as “biased grating”.

Known solutions for making asymmetrical structures involve dose modulation electron beam lithography (usually referred to by the acronym EBL).

EBL is known to enable making of staircase type structures with several steps by modulating the dose deposited locally in the positive resin.

In order to obtain structures with asymmetrical inclinations and without stairs, the two approaches below are possible.

A first approach consists in increasing the number of steps for a given staircase height. Each of the steps then has a smaller height and the general profile of the structure approaches an inclined sidewall. This first approach has the drawback of not eliminating the presence of steps. Especially, it has the drawback of a particularly high making time and therefore a particularly high cost.

A second approach consists in making the resin flow, i.e. in imposing an annealing of the resin above its glass-transition temperature, in order to smooth the staircase profile. This approach was proposed in the article “Fabrication of 3D patterns with vertical and sloped sidewalls by grayscale electron-beam lithography and thermal annealing” published by Arne Schleunitz, Helmut Schift in the journal Microelectronic Engineering, 88 (2011) 2736-2739 .

FIGS. 1A to 1D are derived from this article. FIGS. 1A and 1B are photos taken by scanning electron microscope (SEM) of a staircase-like shaped multilevel structure having four steps 22-25 and three steps 22-24 respectively.

The staircase-like shaped structure includes a portion 10 forming the top of the stairs and a portion 20 forming the steps 22-25.

The portion 10 has a top 12 and a sidewall 11 perpendicular to the substrate. The portion 10 has not received any dose.

The portion 20 is formed in a portion of the positive resin having received a dose that is too low to be completely developed.

FIGS. 1C and 1D illustrate the results obtained after creeping of the structures of FIGS. 1A and 1B respectively. Each of these structures has a sidewall 11 formed by the portion 10 and whose inclination is different from that of the sidewall 21 obtained by creeping of the portion 20.

In practice, it turns out that this type of solutions is not compatible with production rates and large exposure surfaces. Hence, this limits the use thereof on an industrial scale with reasonable costs.

Moreover, a cutout 13 or a step between the top 12 of the portion 10 is noticed.

Hence, there is a need for proposing a solution to attenuate, or still to eliminate, at least one of the drawbacks of the solutions of the prior art.

So is an objective of the present invention.

In particular, an objective of the present invention consists in proposing a solution for obtaining a structure having sidewalls with different inclinations at an improved productivity in comparison with known solutions.

The other objects, features and advantages of the present invention will become apparent upon examining the following description and the appended drawings. It goes without saying that other advantages could be incorporated.

### SUMMARY

To achieve this objective, according to one embodiment, the present invention provides for a method for making at least one asymmetrical structure, i.e. a structure comprising patterns preferably having at the same height level sidewalls having different inclinations α211, α221 with respect to a plane (XY) in which primarily extends a face of a substrate on which rests the structure, the method comprising the following steps:

Provide a stack comprising a substrate topped by at least one layer of a photosensitive or electro-sensitive resin, the resin being such that:
when the resin is exposed to an insolation dose D<Dinversion, it has a positive resin behaviour and creeps when it is subjected to a temperature T higher than or equal to a glass-transition temperature Tfluage of the resin, and
when the resin is exposed to an insolation dose D≥Dinversion, it has a negative resin behaviour and does not creep at, or beyond the temperature Tfluage,

Form at least one first pattern by exposure of at least one first area of the resin to a first dose D1≥Dinversion, the first area defining for the structure the first pattern, the first pattern having a contour comprising at least one first sidewall, the first sidewall having a first inclination α211 with respect to said plane (XY),

Before or after formation of the first pattern, form at least one second pattern in particular by exposure of at least one second area of the resin, the second area being at least partially different from the first area, to a second dose D2<Dinversion, then develop the second area so as to leave in place, outside the second area, resin defining the at least one second pattern,

Perform a creeping step by applying to the stack a temperature T≥Tfluage for a controlled duration d, so as to make the second pattern creep without making the first pattern creep, until the second pattern creeps over at least one portion of the first pattern by leaving uncovered at least partially the first sidewall of the first pattern having said first inclination α211, defining at least one second sidewall for the structure, the second sidewall having with respect to said plane a second inclination α221 different from the first inclination α211.

A positive-tone resin is dissolved when exposed to the photon or electron source and then immersed in a developer, for example a weakly basic aqueous solution or solvent. In the context of the present invention, Deactivation refers to as the minimum dose that has to be imparted to the positive resin to be activated, i.e. to be dissolved during the development step. The areas of the positive resin that have not received a higher dose equal to Dactivation are not activated. Hence, these areas remain in place after the development step and form positive resin patterns.

Moreover, these positive resin patterns subsisting after development creep when they are subjected to a temperature higher than the glass-transition temperature (Tfluage) of the resin.

A negative-tone resin reacts in the opposite way. It is the non-exposed areas that are actually dissolved during the development step.

In the context of the invention, it is provided to use a resin that could selectively adopt the behaviour of a positive-tone resin and of a negative-tone resin depending on the dose applied thereto.

More specifically, so-called positive resins are used in their usual range of use, which can adopt a behaviour of negative resins when they are exposed to doses higher than a threshold. The minimum dose that has to be applied to a positive resin to reverse its tone is denoted Dinversion in the present description.

Hence, it is provided to make both patterns formed in positive resin and patterns formed in negative resin in the same material. The patterns formed in the positive resin could creep and therefore have their shapes change, whereas the patterns formed in the negative resin will remain stable and will be barely affected, or not at all, by the creeping step.

Thus, within the same structure:

the negative resin patterns define sidewalls having a first inclination. For example, these patterns have a vertical inclination (perpendicular to one face of the substrate on which the structure rests) and thus define a binary profile.

the positive resin patterns define sidewalls having a second inclination different from the first inclination. Typically, these positive resin patterns have a softer slope than those formed in a negative resin and define analog contours for the structure.

The proposed solution allows reducing the number of steps and therefore the execution time considerably in comparison with the solution of the prior art presented hereinabove and requiring a multilevel start structure.

Hence, the proposed solution allows increasing the production rates considerably.

Moreover, this solution is perfectly compatible with large exposure areas. Indeed, this solution allows forming in a single step quite many patterns at the surface of a substrate and does not require the use of localised lithography such as electron beam lithography.

Furthermore, in contrast with the solution of the above-mentioned prior art, the proposed solution has the advantage of not requiring the use of resins compatible with grayscale lithography.

Moreover, in contrast with the above-mentioned prior art, the proposed solution allows easily avoiding the apparition of a cutout or a step between a first structure portion forming a sidewall having a first inclination and a second structure portion forming a sidewall having a second inclination.

Furthermore, the proposed solution allows obtaining at the positive resin pattern a perfectly analog profile, in contrast with the solutions of the technique based on a large number of steps written in the resin.

Moreover, it turns out that with the proposed method, only a very small discontinuity, and even no discontinuity at all, between the pattern before creeping and the creep-sensitive pattern is observed in the final structure. Thus, the structure features a perfect material homogeneity. Hence, the structure features homogeneous properties throughout its volume, in particular homogeneous properties in terms of resistance to etching. This has many advantages, in particular for subsequent manufacturing steps, consisting for example in transferring the shape of the resin structure into a functional material. Because of this homogeneity of the material forming the structure, it will be possible to replicate the shapes of the latter in a functional layer in a very faithful manner.

Another aspect of the present invention relates to a structure made of a photosensitive or electro-sensitive resin and having:

at least one first sidewall having a first inclination α211 with respect to a plane in which primarily extends a face of a substrate on which rests the structure, and

at least one second sidewall having a second inclination α221 different from the first inclination α211.

The first sidewall consists of a portion of said resin having a negative resin behaviour and the second sidewall consists of a portion of said resin having a positive resin behaviour.

Advantageously, the portions of said resin forming the first sidewall and the second sidewall have the same chemical composition.

For example, the portion of the resin forming the first sidewall has a molar mass different from that of the resin portion forming the second sidewall.

### BRIEF DESCRIPTION OF THE FIGURES

The aims, objects, as well as the features and advantages of the invention will appear better from the detailed description of embodiments of the latter which are illustrated by the following appended drawings wherein:

FIGS. 1A and 1B are scanning electron microscopy (SEM) photos of multilevel structures according to the prior art, i.e. structures having a staircase-like shape.

FIGS. 1C and 1D illustrate the results obtained after creeping of the structures of FIGS. 1A and 1B respectively.

FIG. 2A is a structure that could be obtained by implementing a conventional lithography technique.

FIG. 2B is a structure that could be obtained by making the structure illustrated in FIG. 2A creep, FIGS. 2A and 2B showing symmetrical sidewalls.

FIG. 2C is an asymmetrical structure that could be obtained by implementing the method according to the invention.

FIGS. 3A to 3K schematically illustrate steps of an embodiment of the invention allowing obtaining an asymmetrical structure.

FIGS. 4A to 4G schematically illustrate steps of another embodiment of the invention.

FIGS. 5A to 5J schematically illustrate steps of another embodiment of the invention.

FIGS. 6A and 6B illustrate, respectively in top view and in section, a structure that could be obtained, after creeping, by implementing an embodiment of the invention.

FIGS. 6C and 6D illustrate, in top view and in section, the structure illustrated in FIGS. 6A and 6B that could be obtained after creeping.

FIGS. 7A and 7B are respectively a schematic illustration in top view and a perspective photo of a structure that could be obtained, after creeping, by implementing an embodiment of the invention.

FIGS. 7C and 7D correspond to the structures of the illustrations 7A and 7B that could be obtained after creeping.

FIG. 8 is a diagram showing an example of evolution of the inclinations of the patterns formed by a positive resin, as a function of the creep conditions.

FIG. 9 is a perspective photo illustrating an example of a network with a line structure that could be obtained with the method according to the invention.

FIGS. 10A and 10B are sectional photos, with decreasing magnifications, of a line structure shown in FIG. 9.

FIGS. 11A and 11B are perspective photos, respectively before and after creeping of a structure comprising parallel lines formed by a stabilised resin and plots formed by a positive-tone resin sensitive to creeping.

FIG. 12 schematically illustrates a structure having two sidewalls having different inclinations inclined with respect to the normal to the substrate on which the structure rests.

FIGS. 13A to 13G schematically illustrate steps of an embodiment of the invention allowing obtaining the structure illustrated in FIG. 12.

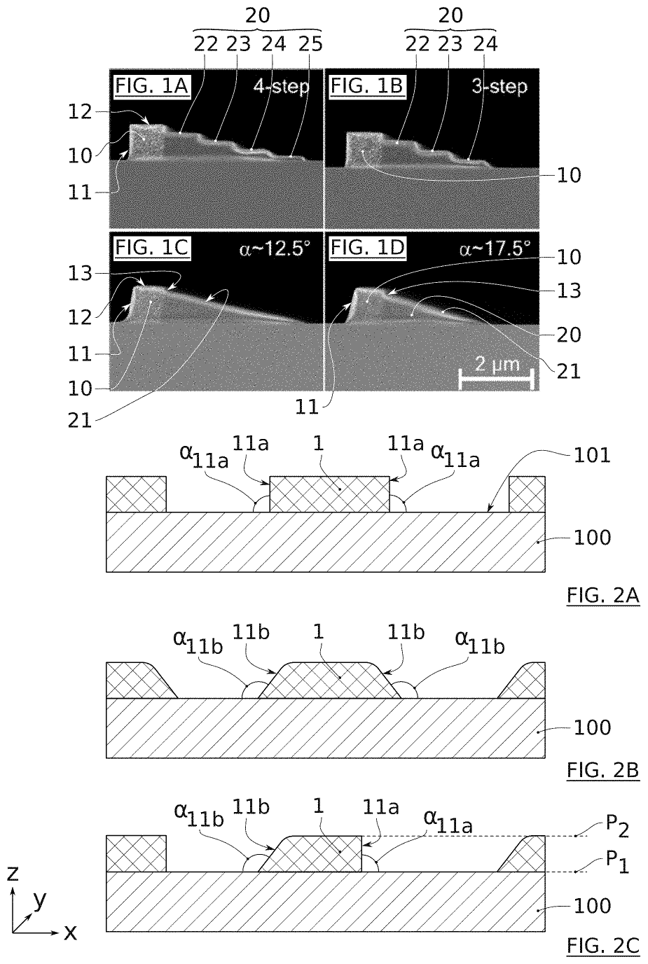

The drawings are provided as examples and do not limit the invention. They consist of schematic principle representations intended to facilitate the understanding of the invention and are not necessarily to the scale of practical applications. In particular, the relative thicknesses of the different layers and of the different patterns do not necessarily represent the reality.

### DETAILED DESCRIPTION

Before starting with a detailed review of embodiments of the invention, optional features that could possibly be used in combination or alternatively are set out hereinafter.

According to one example, the step of forming the second pattern is performed after the step of forming the first pattern.

According to one example, the resin of the at least one layer exposed to form the first pattern is identical, in particular it has the same chemical nature, as the resin of the at least one layer exposed to form the second pattern. Thus, the structure comprising the first and second patterns is perfectly homogeneous. This allows considerably simplifying the subsequent steps of the method, and in particular the steps of transferring the structure into another substrate with a high accuracy.

According to one example, the step of forming the first pattern and the step of forming the second pattern are performed so that before the step of creeping the second pattern is in contact with the first pattern. Thus, the resin portions forming the first sidewall and the second sidewall are in contact. They join together by at least one contact point. The at least one contact point is the top of at least one of the two portions and preferably, yet not necessarily, the tops of the two portions.

According to one example, the structure forms a continuous contour supporting the first sidewall and the second sidewall.

According to one example, the step of forming the at least one first pattern and the step of forming the at least one second pattern are performed in the same lithography equipment and without removing the stack from said equipment between these two steps.

Thus, a step of realigning the masks between each of the exposure steps is avoided. Thus, the accuracy of the alignment of the stabilised patterns and of the creep-sensitive patterns is considerably improved. Moreover, the number of steps is reduced in comparison with a method that involves a realignment of the masks.

According to one example, the method comprises, after the step of forming the first pattern and before the step of forming the second pattern, a step of depositing an additional layer of said resin, the second area exposed to form the second pattern being embedded in the additional layer and the second pattern being formed in the additional layer.

According to one example, the additional layer and the layer in which the first patterns are formed have the same nature, i.e. the same chemical composition. Moreover, upon completion of deposition thereof, both of them have a positive tone.

According to one example, before the creeping step the second pattern covers a top of the first pattern and at least one portion, and preferably the entirety, of the height, of a portion of the contour of the first pattern, the height being considered according to a direction normal to a plane in which primarily extends the face of the substrate on which rests the resin layer.

According to one example, the step of forming the first pattern and the step of forming the second pattern are performed so that after the step of creeping the second pattern, the second pattern covers at least one portion of the contour of the first pattern, preferably is in contact with a portion of the first pattern, without covering a top of the first pattern.

According to one example, during the step of forming the first pattern, the exposure of the at least one first area to the dose D1 simultaneously exposes, at the periphery of the first area, a portion of the second area to a dose higher than or equal to Dactivation and lower than Dinversion, so that before the creeping step the second pattern is at a distance from the first pattern.

According to one example, before the creeping step the second pattern is at a distance from the first pattern, the dimensions of the second pattern and the creep conditions, in particular the duration d and the temperature T, are set so that at the end of the creeping step the second pattern is in contact with the first pattern.

Preferably, the dimensions of the second pattern and the creep conditions are set so that at the end of the creeping step a top of the second pattern is in contact with a top of the first pattern.

According to one example, the inclination of said first sidewall of the first pattern forms a right angle with said plane XY in which extends said face of the substrate.

Before the formation of the at least one first pattern, the method comprises:

a step of forming at least one prior pattern by exposing at least one prior area of the resin to a dose Dp≤Dinversion and then developing the at least one prior area so as to define the at least one prior pattern,

a step of creeping the at least one prior pattern so that the prior pattern comprises at least one sidewall having said first inclination a and intended to form said first sidewall.

According to one example, the exposure of at least one first area of the resin to a first dose D1≥Dinversion is applied to the prior pattern, so as to define said first pattern whose first sidewall has said first inclination.

According to one example, the inclination of said first sidewall of the first pattern forms an angle α with said plane XY, with 90°<α211<180° and preferably with 95°≤α211≤175°.

According to one example, the step of exposing at least one first area of the resin with a first dose D1Dinversion is applied over the entire structure.

According to one example, the method comprises, after the step of forming the first pattern and before the step of forming the second pattern, a step of depositing an additional layer of said resin, the second area exposed to define the second pattern being embedded in the additional layer and the second pattern being formed in the additional layer.

According to one example, the step of forming the first pattern, the step of forming the second pattern and the creeping step are performed so that at the end of the creeping step a top of the first pattern is in contact with a top of the second pattern.

According to one example, the top of each pattern is the uppermost point of this pattern.

According to one example, the method comprises, after the creeping step, a step of insulating at least the second pattern with an insulation dose Df≥Dinversion.

This step allows stabilising the resin. The patterns formed by creeping then are no longer, or are less, sensitive to hear and preserve the geometry obtained at the end of the creeping step.

Moreover, this stabilisation step also allows improving the chemical homogeneity of the resin forming the first and second patterns. The structure formed by the first and second patterns then has a perfectly homogeneous behaviour in the space. For example, it has, over the entirety of its volume, homogeneous etching-resistance properties. This is particularly advantageous for the subsequent steps, in particular those during which the resin structure will be transferred by etching into another material.

According to one example, the first pattern and the second pattern rest on the same layer by being in contact with this layer.

Preferably, the first pattern and the second pattern are in contact with an upper face of the substrate.

Advantageously, the first pattern and the second pattern are formed in the same resin. This allows simplifying the subsequent integration steps.

Indeed, the first pattern and the second pattern have identical behaviours, for example to etching which is particularly advantageous when the structure will be transferred by etching into an underlayer.

In the context of the present invention, an organic or organo-mineral material that could be shaped through an exposure to an electron, photon, X-ray beam, a light beam in the ultraviolet, extreme ultraviolet (EUV) or deep ultraviolet (Deep UV) range typically in the range of wavelengths from 193 nm to 248 nm, the emission lines of a mercury lamp, namely: 365 nm for the I line, 435 nm for the G line and 404 nm for the H line, is referred to as a resin. The invention also applies to the resins that could be mechanically shaped, in particular by thermally-assisted printing or by ultraviolet.

In the context of the present invention, the used resins are positive-tone resins commonly used in lithography. These positive-tone resins could have their tone reversed, to have a negative-tone resin behaviour when they receive a dose higher than a dose Dinversion.

It is said that a positive resin has its tone reversed to become a negative resin if, after having exposed an area of the positive resin by applying a dose D≥Dinversion thereto:

the pattern defined by the exposed area does not creep at the glass-transition temperature of the same resin when it presents its positive resin initial behaviour.

This exposed area remains in place upon completion of a conventional development step, which development steps would allow making the areas of this resin exposed to a dose higher than the activation dose Dactivation disappear.

There are several methods for determining whether a resin has this capability to have its tone reversed. For example, it is possible to implement, for this resin, a contrast curve, well known to a person skilled in the art. To implement this curve, it is possible to measure the thickness of the remaining resin after development as a function of the exposure dose applied to the resin, this exposure dose being chosen in a range much higher than the range commonly used for this resin.

The contrast curve then has on the abscissa axis the applied doses and on the ordinate axis the measured resin thicknesses after each exposure and development cycle. Typically, for an abscissa value comprised between zero and Dactivation, the curve corresponds to a thickness of the resin which remains constant and which is substantially equal to the initial thickness of the resin. For a dose D higher than or equal to Dactivation, the thickness becomes zero because the resin is developed. Then, if an increase of the exposure doses in abscissa causes an increase of the resin thickness, this means that this resin has this inversion behaviour. This increase of the thickness also allows identifying the exposure threshold Dinversion beyond which this inversion is done. Preferably, beyond this threshold Dinversion, the thickness of the resin remains constant and is close to its initial thickness.

As examples of resins commonly used in microelectronics, mention may be made of resins based on methacrylate (for example poly(methyl methacrylate PMMA), polyhydroxystyrene (PHS) and resins based on photo-decomposition principles such as azide quinone resins, i.e. diazonaphthaquinone (DQ).

In the present patent application, an amount of energy received by a resin per unit area is referred to as dose. This energy could be in the form of photons (photolithography) for a photosensitive resin. The dose is then usually expressed in Joules per m², or most often in millijoules (mJ) per cm² (10⁻² m²) namely in mJ/m².

This energy may also be in the form of electrons (electronic lithography) for an electro-sensitive resin. The dose is then commonly expressed in Coulombs per m², or most often in micro Coulombs (μC) per cm⁻² (10⁻² m²) namely in μC/m².

By “nature” of a material such as a resin, it should be understood its chemical composition, i.e. the nature and the proportion of the species forming the material. Two layers are considered as being made of the same resin if they have the same chemical composition.

The same resin may have areas whose behaviours differ from the development solutions. The differentiation of these areas is obtained by the energy dose applied upon an exposure to each of these areas. Thus, these areas differ by their molar mass. For example, it is possible to measure these molar masses by chromatography or by mass spectrometry.

Thus, two portions or areas of the same resin may have the same chemical composition but have different tonalities.

In the present patent application, the thickness of a layer is measured according to a direction perpendicular to a plane in which primarily extends the substrate on which rests the layer. In the figures, this thickness is measured according to the direction Z of the orthogonal reference frame XYZ.

When it is indicated that an element, for example a resin area, is located in line with another element, for example the opening of a mask, this means that these two elements are located on the same line perpendicular to the main plane in which primarily extends a face of the substrate, i.e. on the same line directed vertically in the figures.

In the present patent application, an inclination a formed by a profile or a sidewall of a pattern corresponds to the angle formed between the surface on which rests this pattern and the tangent to this profile or this sidewall at the contact between the latter and said surface.

It is specified that, in the context of the present invention, the terms “on”, “tops”, “covers”, “underlying”, “opposite each other” and their equivalents do not necessarily mean “in contact with”. Thus, for example, the deposition, the attachment, the gluing, the assembly or the application of a first layer over a second layer, does not necessarily mean that the two layers are directly in contact with each other, but means that the first layer covers at least partially the second layer by being either directly in contact with it, or by being separated from it by at least one other layer or at least one other element.

Similarly, when it is indicated that a pattern or a structure is atop a substrate, this could mean that the pattern or the structure are directly in contact with the substrate or that one or several layer(s) are interposed between the pattern or the structure and the substrate.

The term “step” does not necessarily means that the actions conducted during one step are simultaneous or immediately successive. In particular, some actions of a first step could be followed by actions related to a different step, and other actions of the first step could be resumed afterwards. Thus, the term step should not necessarily be understood as unitary actions inseparable over time and in the sequence of the phases of the method.

The invention will now be described with reference to FIGS. 2A to 13G.

Before describing in detail the steps of several examples of a method according to the invention, the paragraphs hereinbelow explain how the invention uses properties of the lithography resins.

In their standard use, it is possible to form binary structures in the resin, i.e. structures having vertical sidewalls. As illustrated in FIG. 2A, this structure 1 type has sidewalls 11a forming a right angle α11a with a face 101 of the substrate 100 on which rests this structure 1.

It is also possible to use another property (flow property) of the resins when they are subjected to a thermal annealing. This method commonly called “resin creeping” or “resist reflow” is well known to a person skilled in the art. This creeping method allows modifying the initial binary shape of the resin structure to transform it into a shape with rounded or analog profiles. Such a structure is illustrated in FIG. 28. This structure 1 has sidewalls 11b whose inclination α11b is larger than 90°, α11b is the angle formed between the plane XY in which the face 101 of the substrate 100 is primarily contained and the tangent to the sidewall 11b at the contact between this sidewall 11b and the face 101 on which rests this pattern 220.

Nonetheless, when these creeping processes are implemented, they modify the entire shape of the initial resin structure without being able to introduce an asymmetry therein at the inclination of these sidewalls 11a or 11b. Indeed, the entire resin structure 1 creeps homogeneously.

The present invention benefits from these two properties of the resins to make a structure in one single and same material but on which an asymmetrical creeping could be applied to create binary and analog profiles. Thus, and as illustrated in FIG. 2C, such a structure 1 has at least one sidewall 11a having a first inclination α11a, for example a right angle, and at least one sidewall 11b having a second inclination α11b different from the inclination α11a. This structure could be qualified as asymmetrical since the sidewalls located on either side of a plane perpendicular to the face 101 of the substrate 100 have different inclinations.

In a particularly advantageous manner, the method according to the invention allows that these sidewalls 11a, 11b having different inclinations are located at the same level. Thus, these sidewalls 11a, 11b extend at least partially between two planes P1, P2 distance from each other and parallel to the plane XY in which primarily extends the face 101 of the substrate 100. The planes P1 and P2 as well as the plane XY of the orthogonal reference frame XYZ are referenced in FIG. 2C.

To achieve this result, one could consider applying the following steps to a structure having at least one positive resin layer 200 which could:

be activated when it is exposed to a dose D2, such that DactivationD2. The activated resin areas then could be dissolved during a development step. The areas that remain in place after development of the activated areas could creep when the resin is subjected to temperatures T higher than or equal to a creep temperature Tfluage,

stabilise and thus not creep when it is subjected to the glass-transition temperature Tfluage of this positive resin. This stabilisation is obtained by exposing the resin to an insolation dose D≥Dinversion. It is then considered that the resin has its behaviour reversed so as to feature a negative resin behaviour.

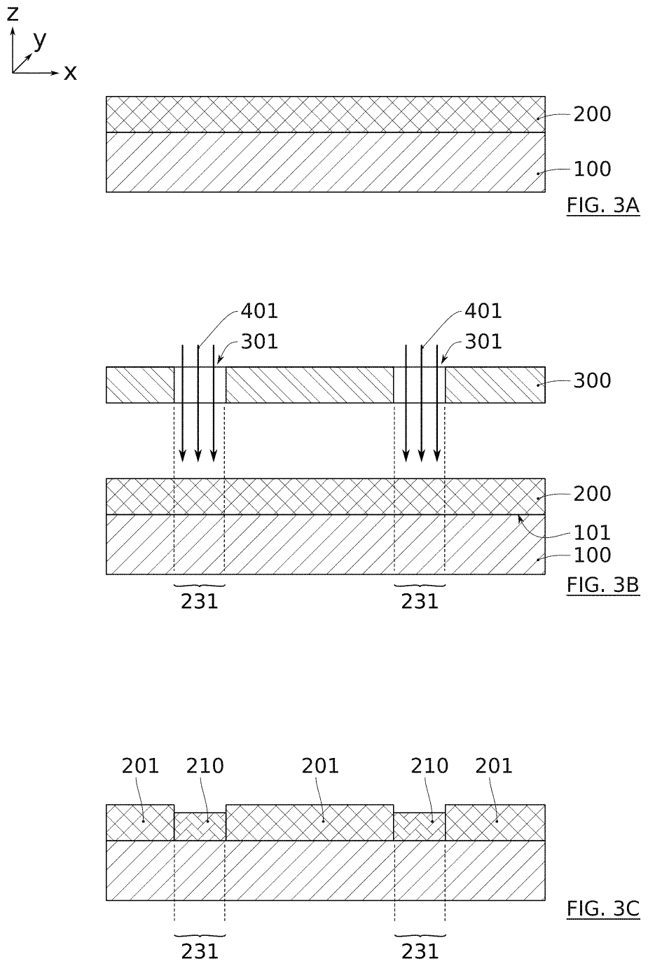

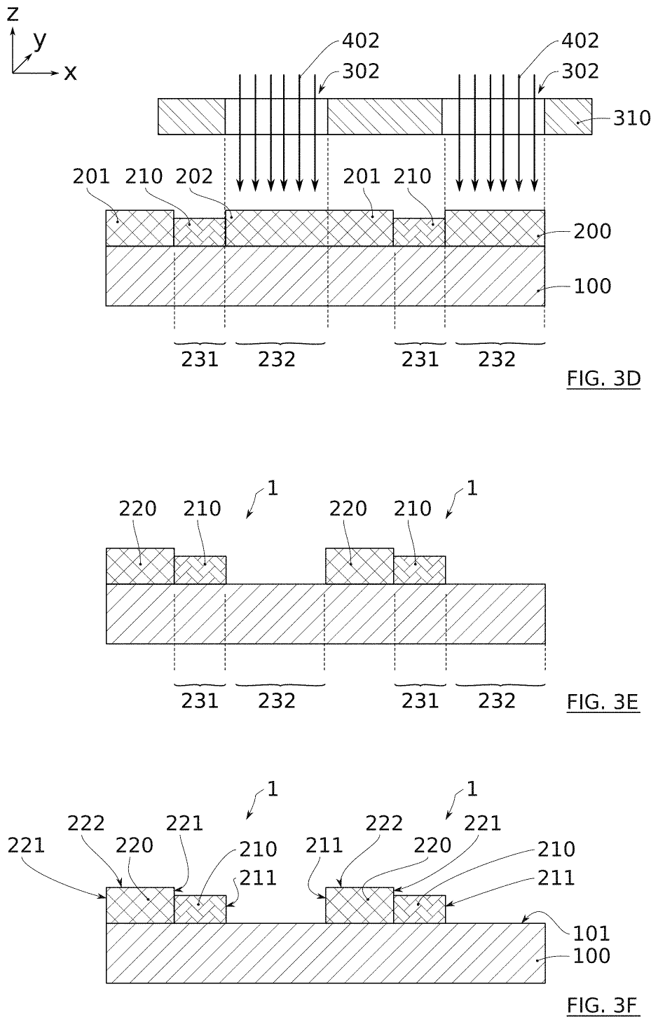

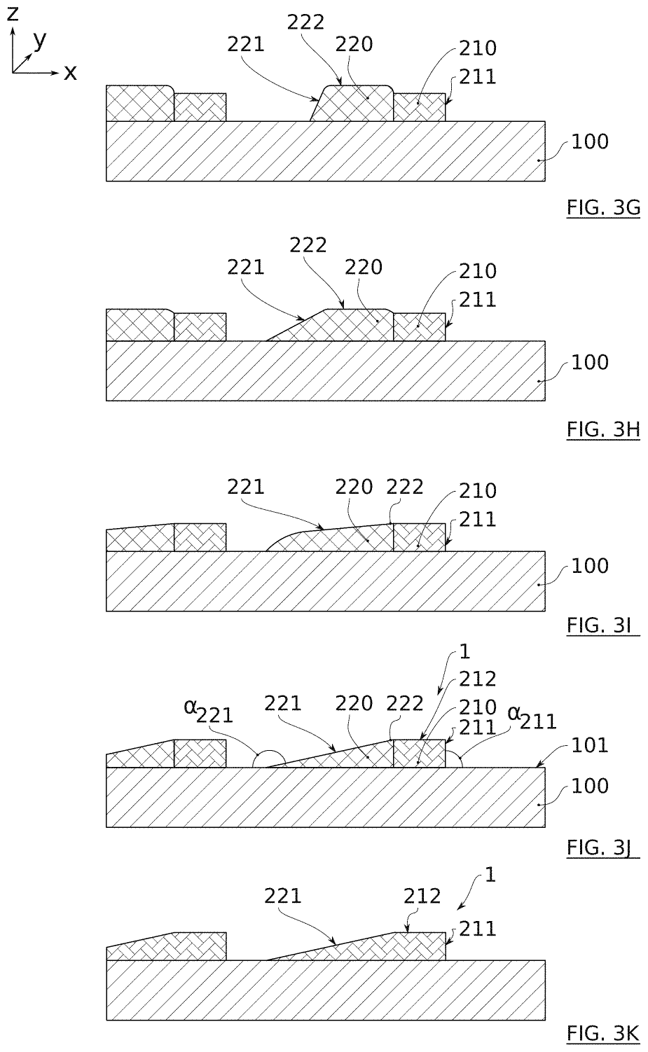

Starting from a resin having the above-mentioned properties, the proposed method provides for the following steps which will now be briefly described. These steps will be described in more detail later on with reference to FIGS. 3 to 13.

During a first step, a resin area with a dose D1≥Dinversion so as to form a stabilised pattern 210, i.e. a pattern that does not creep at the glass-transition temperature Tfluage. This first pattern 210 has a first inclination α211 with respect to the plane XY.

During another step, performed before or after the above-mentioned step, another area of the resin is exposed to a dose Dactivation≤D2<Dinversion. This other area of the resin having a positive resin behaviour, the exposure to the dose D2 is followed by a development and leaves another pattern 220 in place. This other pattern 220, formed by development of the positive resin, is sensitive to creeping.

A structure 1 comprising the stabilised pattern 210 and the positive resin pattern 220 is then obtained on a face 101 of the substrate 101.

Afterwards, a creeping step is performed by applying a temperature T≥Tfluage to the structure for a controlled period d, so as to make the positive resin pattern 220 creep. This temperature T does not allow making the stabilised pattern 210 whose behaviour is that of a negative resin creep. This creeping is carried on until the pattern 220 creeps over a portion of the pattern 210. The structure 1 then comprises:

a sidewall 211 whose inclination α211 is defined by the stabilised pattern 210;

a sidewall 221 whose inclination α221 is defined by the pattern 220 that has crept.

A resin structure 1 having different inclinations α211, α221 is then obtained.

Particular embodiments will now be described in detail with reference to FIGS. 3 to 13.

FIGS. 3A to 3K illustrate a first embodiment of the method.

FIG. 3A illustrates an example of a stack starting from which the method is implemented. This stack comprises a support substrate 100 topped by a positive resin layer 200.

FIG. 3B illustrates a step 401 of exposing the resin 200 through a mask 300 including openings 301. The areas 231 located in line with the opening 301 receive an energy dose D1 in the form of photons (optical lithography) or electrons (electronic lithography).

The applied dose D1 is much higher than the use dose recommended for this positive resin. This dose D1 is higher than the stabilisation threshold Dinversion. Thus, the exposed areas 231 delimit stabilised patterns 210 and having a negative-tone resin behaviour.

As illustrated in FIG. 3C, the areas 201 of the resin layer 200 that have not been exposed keep their positive-tone resin behaviour.

As illustrated in FIG. 3D, it is then proceeded with a second lithography, configured to expose other areas 232 of the resin layer 200 through a mask 310. These areas 232 are at least partially different from the areas 231.

This exposure applies to the areas 302 a dose D2 higher than the dose Dactivation required for the activation of the resin, but lower than the dose Dinversion required to reverse the tone of the resin. Thus, Dactivation≤D2<Dinversion.

According to a first embodiment, illustrated in FIG. 3D, this second exposure 402 is carried out through a mask 310 different from the first mask 300. This mask 310 may have openings 302 different from those of the mask 300, in particular in terms of dimensions, location or number.

According to another embodiment, the masks 300 and 310 are identical, and the second exposure 402 is performed by offsetting the mask with respect to the position that has been assigned thereto during the first exposure 401.

Thus, are obtained within the same resin layer 200:

non-exposed and therefore non-activated resin portions 201,

portions having a negative resin behaviour and delimiting the stabilised patterns 210,

activated positive resin portions 202, located in line with the areas 232.

Afterwards, a step of developing the resin with a solution allowing dissolving the activated positive resin portions 202 is performed.

As illustrated in FIG. 3E, hybrid structures 1 are thus obtained on the same substrate 100, each structure 1 including at least one pattern 210 whose behaviour is that of a negative-tone resin and at least one pattern 220 formed by the positive-tone resin portions 202.

In an optional and particularly advantageous manner, the first exposure 400 and the second exposure 402 are performed while keeping the stack 100, 200 in the same lithography equipment. Thus, the stack 100 is not unloaded off the equipment at the end of the first exposure 401 and before performing the second exposure 400.

This is made possible by the fact that no development step is performed between the first exposure 401 and the second exposure 402.

This allows self-aligning the negative-tone patterns 210 and the positive-tone patterns 220. The dimensional control of the structure that is ultimately obtained is thereby significantly improved. The deformations of the strata and the alignment errors that might be encountered when the successive steps are aligned are also avoided based on marks generated in the substrate 100.

As illustrated in FIG. 3F which replicates FIG. 3E, the patterns 210 have sidewalls 211 extending perpendicularly to the face 101 of the substrate 100 (if the direction of the photon electron beam used for the exposure is perpendicular to the main plane in which extends the resin layer 200). Similarly, the patterns 220 have sidewalls 221 perpendicular to this face 101.

Afterwards, it is proceeded with a step of creeping the hybrid structures 1. The stack is subjected to a temperature T higher than the glass-transition temperature Tfluage of the initially deposited positive resin as illustrated in FIG. 3A.

FIGS. 3G to 3J illustrate different configurations reached by the resin as time elapses during this creeping step.

As it appears on each of these figures, the patterns 210 having a negative resin behaviour do not deform. The patterns 220 having a positive resin behaviour creep and deform. Their sidewalls 221 round or tilt forming with the face 101 of the substrate 100 an angle α221>90°. α221 is the angle formed between the plane XY and the tangent to the sidewall 221 at the contact between the sidewall 221 and the face 101 on which this pattern 220 rests. α221 evolves as the duration of creeping increases. Typically, α221 deviates from a 90° value over time. The entire surface of the sidewall 221 does not necessarily have the same inclination or the same slope. Some portions of the sidewall 221 could be rounded.

The faces 211 of the patterns 210 keep their initial inclination α211, for example an inclination equal to 90°.

Preferably, it is provided that at the end of the creeping step, the top 212 of the patterns 210 is at the same height level as the tops 222 of the patterns 220. Preferably, these tops are in contact so as to feature continuity between these patterns. According to one example, the structure 1 forms a continuous contour supporting the first sidewall 211 and the second sidewall 221.

To obtain the desired final shape, for example to obtain a material continuity between the tops 212 and 222, the following parameters should be properly selected in particular: the nature of the resin, the creeping time, the creep temperature, the volumes and the shapes of the patterns 220 as well as the relative position of the patterns 210 and 220.

In the example illustrated with reference to FIGS. 3A to 3J, before the creeping step, the patterns 210 and 220 of each structure 1 are adjacent or in contact with each other. According to an alternative embodiment, it is possible to provide for these patterns 210 and 220 not being in contact before the creeping step but become so upon completion of the creeping step. For this purpose, the volume of the patterns 220, the distance between these and the patterns 210 before creeping, as well as the parameters of the creeping step, in particular the temperature and the creeping time, should be set.

In the example illustrated with reference to FIGS. 3A to 3J, the areas 231 intended to form the stabilised patterns 210 are exposed before the areas 232 intended to form the negative resin patterns 220. According to an alternative embodiment, it is possible to provide for a reverse chronology. Thus, it is possible to firstly define the negative resin patterns 220 by exposing the areas 232 and then it is possible to form the stabilised patterns 210 by exposing the areas 231. This embodiment amounts to reversing the steps illustrated in FIGS. 3B and 3C with the steps illustrated in FIG. 3D.

In an optional yet particularly advantageous manner, once the creeping step is completed, it is proceeded with a step of stabilising the structure 1. This stabilisation step allows for a better homogeneity of the resin. This allows obtaining identical properties, for example in terms of etching-resistance, over the entire volume of the structure 1. This is particularly advantageous for the subsequent steps of the method, in particular during the transfer, by etching, of the shape of the structure 1 into a functional layer, for example in a material such as one of the following materials: Si, SiO2, SiN, metal, dielectric. The etching selectivity between this material to be etched and the resin will be homogeneous in contrast with what would have happened if the crept and stabilised resin portions were different. By implementing the method according to the invention, all of the portions of the structure 1 will be etched at the same rate and the dimensions of the structure 1 will then be faithfully transferred into the functional layer.

For example, this stabilisation step is obtained by exposing the entire structure 1 to a dose higher than Dinversion.

It should be noted that there are other solutions to carry out this stabilisation step. For example, thermosetting resins could be stabilised by applying thereto an annealing temperature that is higher than the creep temperature. Naturally, the creeping kinematics should be controlled relative to the heat crosslinking kinematics, which is done by a person skilled in the art without any difficulty.

Thus, the proposed method allows obtaining a structure 1 having sidewalls with different inclinations α211, α221, without having a staircase-like profile and without the need for using electron-beam lithographies. The proposed method could be applied over a large surface to make a large number of patterns during each of the steps. Hence, this method is perfectly compatible with the industrial productivity requirements.

Moreover, these methods do not require the use of grayscale resins and lithographies.

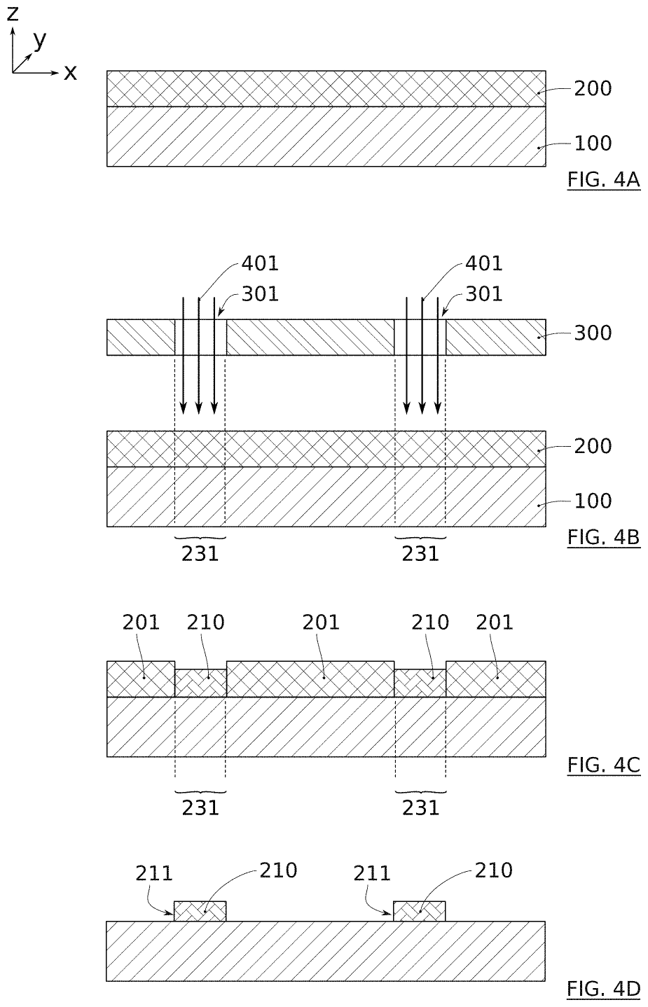

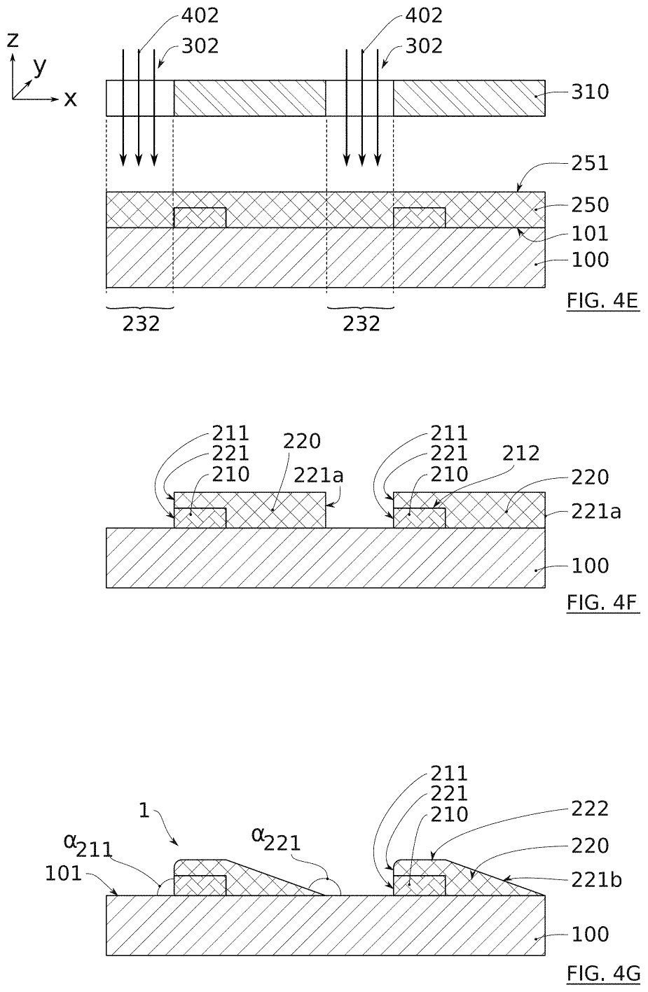

Another way for carrying out the present invention will now be described with reference to FIGS. 4A to 4K.

This embodiment differs from the embodiment of FIGS. 3A to 3K primarily in that the resin is developed after formation of the stabilised patterns 210 and the creep-sensitive patterns 220 are formed in a resin layer 250 affixed on the patterns 210. This embodiment is described in detail hereinbelow.

The initial steps, illustrated in FIGS. 4A and 4C, correspond to those described with reference to FIGS. 3A and 3C.

As illustrated in FIG. 4D, after exposure of the areas 231 to delimit the patterns 210 in the resin 200, it is proceeded with a step of developing the resin located in the areas 201 adjacent to the areas 231 having received an exposure dose higher than the inversion dose Dinversion.

To carry out the development of the resin in these areas 201, it is possible to resort to several solutions. According to a first solution, an additional exposure is performed, for example full plate and after removal of the mask 300, with a dose higher than Dactivation and strictly lower than Dinversion. A conventional development step will allow removing the areas 201.

According to a second solution, after the step of exposing the areas 231 to a dose D higher than or equal to Dinversion, a step of rinsing with a solvent is performed to remove the non-exposed resin that is located outside the patterns 210. This step of rinsing with a solvent allows developing the positive resin that has not been exposed in the areas 201. A variant of this second solution may consist in performing a conventional development and then a step of rinsing with a solvent.

The solvent that could be used is that one implemented to dilute the resin to form a deposit by centrifugation. Usually, this solvent for the photolithography resins is mainly 2-methoxy-1-methylethyl acetate.

A conventional development is more particularly advantageous in an embodiment wherein after the stabilisation of the first patterns, a second exposure of the resin to a dose higher than Dactivation but lower than Dinversion is carried out.

Thus, the non-exposed portions 201 are dissolved. Hence, only the patterns 210 remain on the substrate 100. In this example, these patterns 210 typically have vertical sidewalls 211, in particular if these patterns 210 are formed by lithography through a conventional mask 300 with an optical or electronic beam whose preferential direction is perpendicular to the face 101 of the substrate 100.

Upon completion of Step 4D, it is proceeded with the deposition of an additional layer 250 of a positive-tone resin. Preferably, this additional layer 250 is identical to the layer 200 from which the patterns 210 have been formed. Thus, the layers 200 and 250 have the same chemical composition, i.e. the same species are present therein in similar proportions. Preferably, this additional layer 250 is deposited over the entire substrate 100. Preferably, this additional layer 250 has a planar upper face 251 parallel to the face 101 of the substrate. Hence, this does not consist of a conformal deposition. Preferably, this additional layer 20 entirely covers the patterns 210. For example, this deposition is performed by spin coating.

FIG. 4E illustrates a step 402 of exposing the layer 250 through a mask 310 having openings 302. The exposed areas 232 receive a dose D2Dactivation.

FIG. 4F illustrates a development step to remove the exposed portions of the positive resin. For this development step, a conventional solution allowing dissolving the exposed portions of the positive resin will be used. The non-exposed portions define the patterns 220 formed by a positive-tone resin.

Preferably, these patterns 220 cover at least one portion of the patterns 210. Advantageously, they cover at least one portion of the contour of the patterns 210 and leave at least one portion of the height of some sidewalls 211 of the patterns 210 uncovered.

In the illustrated example, the patterns 220 cover the entire top 212 of the patterns 210 and leave the sidewall 211 of these patterns 210 entirely uncovered.

Step 4G illustrates the result of a creeping step applied to the structure 1. Only the pattern 220 deforms. Thus, the pattern 210 defines for the structure 1a sidewall 211 with an inclination α211, for example vertical.

The pattern 220 defines for the structure 1a sidewall 221 with an inclination α221 different from α211 and non-vertical.

This embodiment is particular in that it involves a step of developing the resin after formation of the stabilised patterns 210 and before formation of the positive resin patterns 220. Henceforth, the plate, i.e. the stack comprising the substrate 100 and the structures 1, has to be removed off the lithography equipment having been used to make the patterns 410. After development of the resin (FIG. 4D), it is then necessary to load the plate again in the lithography equipment and to perform an alignment step so that the patterns 410 are aligned with the patterns 420 that should be created. Since the plate has not undergone any step that causes a deformation of its exposure stratum, as would be the case with an etching step or a heat-treatment step at high temperature, the realignment of the plate with respect to the patterns 210 could be done with a very good accuracy.

Advantageously, the proposed method is also applicable to the case where the lithography masks used to define the stabilised patterns 210 have relatively limited performances. Conventional lithography masks, which have the advantage of being less expensive than complex masks such as phase-change masks, could lead to an unintentional exposure of the areas adjacent to the areas that should be exposed. Despite these low performances of the masks, the proposed method allows defining asymmetrical structures whose shapes are accurately controlled.

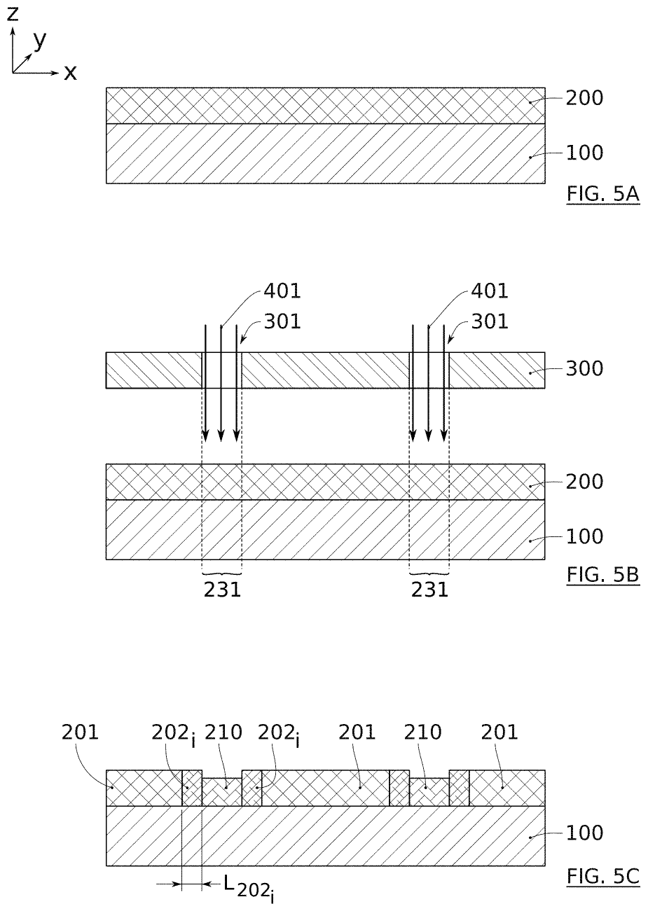

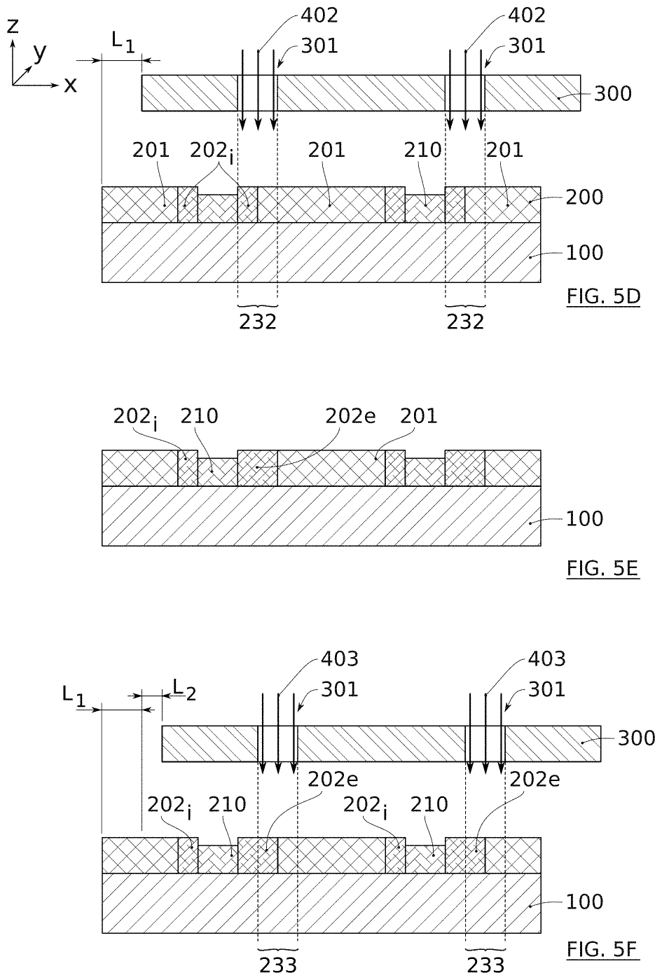

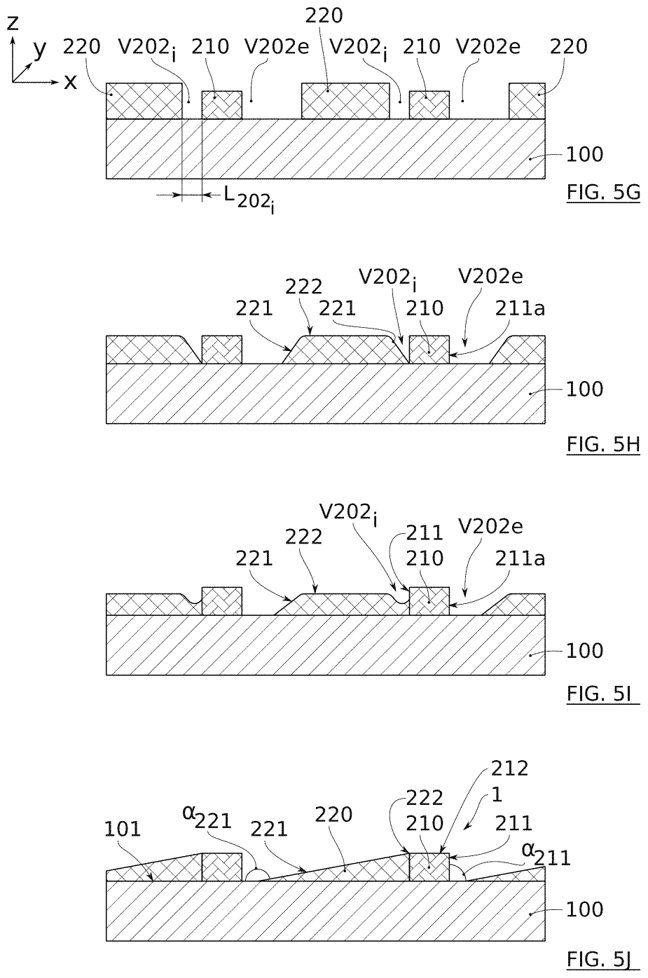

An embodiment of the method offering this advantage will be described in detail with reference to FIGS. 5A to 5J.

The initial steps, illustrated in FIGS. 5A and 5B, correspond to those described with reference to FIGS. 3A and 3B.

During the exposure 401, the photon or electron flux exposes the areas 231 through the openings 301 of the mask 300. The dose D1 imparted to these areas 231 is higher than Dinversion, thereby defining stabilised patterns 210.

Still during this exposure 401, and as illustrated in FIG. 5C, it is possible that areas 202i peripheral to the area 231 are also exposed but to lower doses D3 (D3<Dinversion). Most often, this exposure of the peripheral areas 202i is unintentional. As indicated hereinabove, it results from the exposure conditions and in particular from the properties of the mask.

Nonetheless, this dose D3 could be enough to activate the positive resin at these areas 202i (D3≥Dactivation). This peripheral exposure then defines latent images in the resin which could be revealed in case of development of the resin. However, the development of the resin is not performed after the first exposure 401. The resin layer 200 then has non-activated portions 201, activated portions 202i and stabilised portions having a positive resin behaviour.

Advantageously, the plate comprising the stack is not unloaded off the lithography equipment and a new exposure 402 of the resin 200 is performed through a mask.

This exposure 402 is performed so as to impart a dose D4 to areas adjacent to at least some of the activated portions 202i or areas 232 that overlap these, so as to form enlarged portions 202e.

This dose D4 is set so that the cumulative doses received by the positive-tone resin are higher than the activation dose Dactivation and are lower than the inversion dose Dinversion.

This new exposure 402 could be performed through the mask 300, by offsetting the latter with respect to its position during the exposure 401. This offset is referenced L1 in FIG. 5D.

As illustrated in FIG. 5E, the resin layer 200 then has non-activated portions 201, possibly activated portions 202i defined only by the first exposure 401, activated portions 202e defined by the first 401 and second 402 exposures and stabilised portions having a positive resin behaviour.

Since the plate is not unloaded between the first exposure 401 and the second exposure 402, the alignment errors and constraints are reduced and even suppressed.

During the second exposure 402, it is possible to use the same mask 300 as during the first exposure 401 while offsetting it, as illustrated in FIG. 5D. The alignment of the different patterns and therefore the accuracy of the final structure are thereby improved. Alternatively, it is possible to use another mask.

Optionally, it is possible to proceed with a new exposure 403 performed on an area 233 so as to further increase the size of the portions 202e receiving a dose allowing activating the positive resin. An additional exposure 403 is illustrated in FIG. 5F. For this exposure 403 too, the mask 300 is preferably used which is offset with respect to its previous position (the offset L2 is illustrated in FIG. 5F), this enabling a self-alignment of the patterns. Alternatively, it is possible to use a different mask whose openings allow exposing the areas 233.

Depending on the patterns that should be ultimately obtained, it is possible to carry out other exposures such as those illustrated in FIG. 5F.

These successive exposures 401, 402, 403 cause an enlargement of the exposed negative resin portions 202e on at least one of the sides. This results in making the shape of the latent image asymmetrical.

Once the dimensions determined by the user of the latent images made in the positive-tone resin are reached, the plate is unloaded off the lithography equipment and the resin is developed. The result of this development step is illustrated in FIG. 5G.

The portions 202i and 202e have cumulatively received a dose higher than the activation dose Dactivation (and naturally lower than the dose Dinversion), are dissolved during the development step. These portions 202i and 202e leave recesses referenced v202i and v202e in place in FIG. 5G.

Stabilised patterns 210 having a negative resin behaviour and patterns 220 having positive resin behaviour then subsist on the substrate 100. These patterns 210, 220 do not join together. They are separated at least by a distance L202i corresponding to the dimension of the peripheral areas 202i, this dimension L202i being considered parallel to the plane XY.

Afterwards, it is proceeded with a creeping step.

FIGS. 5H to 5J illustrate different configurations reached by the resin as time elapses during this creeping step. One could wish the creeping of the patterns 220 to be significant enough so that it deforms until coming into contact with at least one stabilised pattern 210. To this end, the following parameters should be properly selected in particular: the nature of the resin, the creeping time and temperature, the volumes and the shapes of the patterns 220 as well as the relative position of the patterns 210 and 220.

Depending on these parameters, it is possible for example to provide for the top 212 of the pattern 220 become flush with, or getting into contact, with the top 212 of the pattern 210. Thus, it is possible to have a continuous and analog profile between the top 212 of the pattern 210 and the sidewall 221 of the pattern 220.

Like for the previous examples, the structure 1 thus obtained includes sidewalls 211 having an inclination α211, for example vertical, and sidewalls 221 having an inclination α221 different from α211.

Since these patterns 210, 220 are formed by an identical resin, the latter could easily wet the surface of the pattern 210 with negative resin and thus form a unique and homogeneous structure for the remainder of the methods.

Like for the previous examples, it is possible to provide for an optional and additional step of stabilising the entire structure 1 by exposing it to a dose higher than Dinversion. This step allows brining the portions defined by the patterns 220 in the same state as those defined by the patterns 210, thereby making the structure perfectly homogeneous.

In the previous examples, the different patterns and structures, illustrated in section (according to the plane ZX), may extend primarily according to a unique direction and are will therefore be called one-dimensional patterns. Alternatively, in all of these examples, the different patterns and structure may extend in two directions and will therefore be called two-dimensional patterns. In the following examples, a 2D pattern is exposed to a dose higher than Dinversion to make it insensitive to creeping whereas another portion of the 2D pattern keeps its sensitivity to creeping.

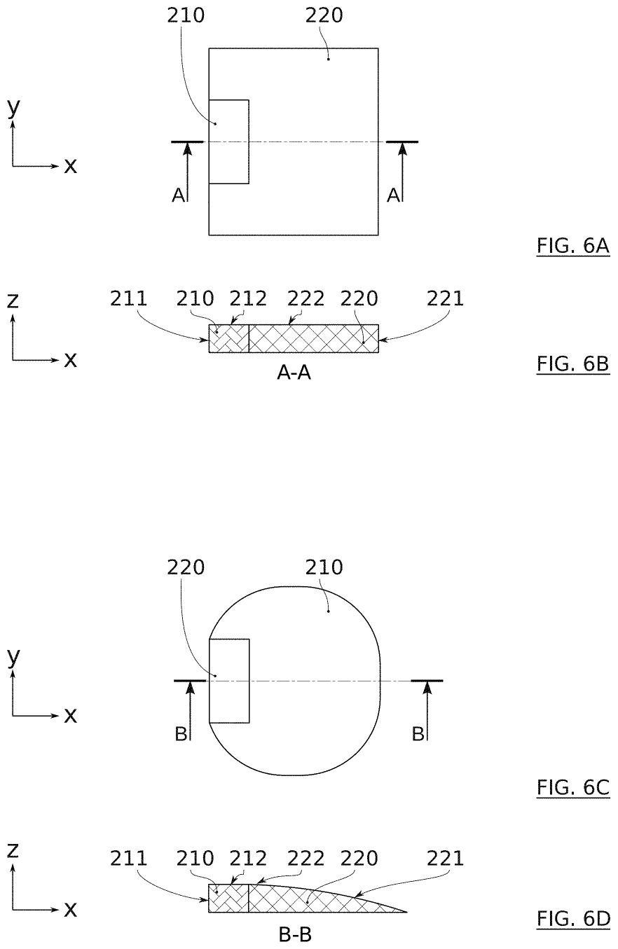

FIGS. 6A to 6D illustrate a first example of a two-dimensional structure that could be obtained by implementing the present invention.

FIGS. 6A and 6B illustrate, respectively in top view and in section according to the plane ZX, a structure that could be obtained, after creeping, by implementing an embodiment of the invention.

For example, this structure is obtained from a square positive resin block. A portion of this block is exposed to a dose Dinversion to define the stabilised pattern 210. The remainder of the resin keeps a positive resin behaviour and forms the pattern 220.

FIGS. 6C and 6D illustrate, respectively in top view and in section, the structure after creeping. The contour of the pattern 220 deforms and rounds by the creeping effect. This contour has an inclined sidewall 221. For example, it is possible to provide for the top 212 of the pattern 210 defining a continuous profile with the top 222 and the sidewall 221 of the pattern 220.

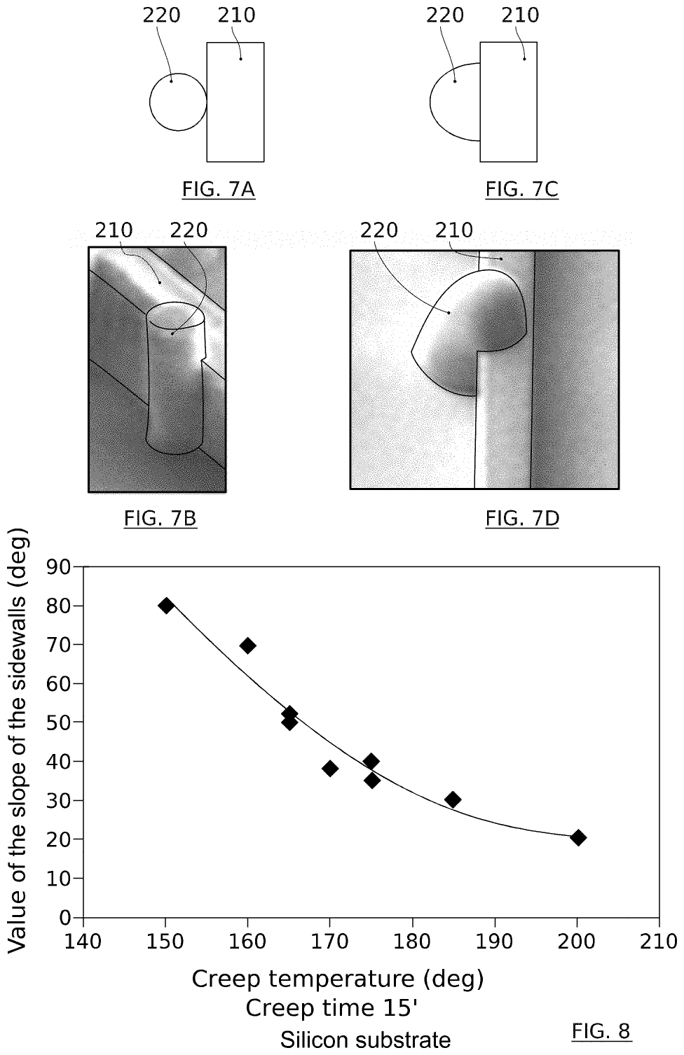

FIGS. 7A to 7D illustrate a second example of a two-dimensional structure that could be obtained by implementing the present invention.

FIGS. 7A and 7B are respectively a schematic illustration in top view and a perspective photo of a structure that could be obtained, before creeping. This structure comprises:

a pattern 210 forming a line or a rib. This pattern 210 has received a dose D≥Dinversion to make it insensitive to creeping.

a pattern 220 forming a plot, for example with a circular section. This pattern 220 has a positive resin behaviour and remains sensitive to creeping.

FIGS. 7C and 7D illustrate the result obtained by creeping of the structure illustrated in FIGS. 7A and 7B. By wetting effect, one could see that the positive resin plots tend to spread over the rib, which does not deform.

The method according to the invention allows making other structure shapes.

### Exemplary Embodiment

A concrete embodiment will now be described.

In the context of this example, a M78Y type optical lithography positive resin supplied by the company FujiFilm(^{T}) is used. In its conventional use, the exposure wavelength for activating this resin is 248 nm (10⁻⁹ m). The thicknesses of the resin are comprised between 500 nm (10⁻⁹ m) and 1 μm (10⁻⁶ m).

The exposure dose required for the activation of the resin in its positive tone mode is close to 20 mJ/cm² for optical lithography. Thus, Dactivation=20 mJ/cm². The exposure dose required for reaching the negative tone mode and making this resin insensitive or barely sensitive to creeping is close to 120 mJ/cm². Thus, Dinversion=120 mJ/cm². These exposure dose values being given for an exposure wavelength of 248 nm.

This resin also has a negative resin mode when it is exposed to electrons at 50 kV for doses higher than 75 μC/cm².

The recommended creep temperature is comprised between 160° C. and 200° C. for durations from a few minutes to 30 minutes.

FIG. 8 is a curve illustrating how to adjust the angles of contact of the resin with the contact surface of the resin as a function of the creep temperature for a given creep duration (15 minutes) with a silicon sublayer or substrate. In this example, it consists of the above-mentioned resin M78Y.

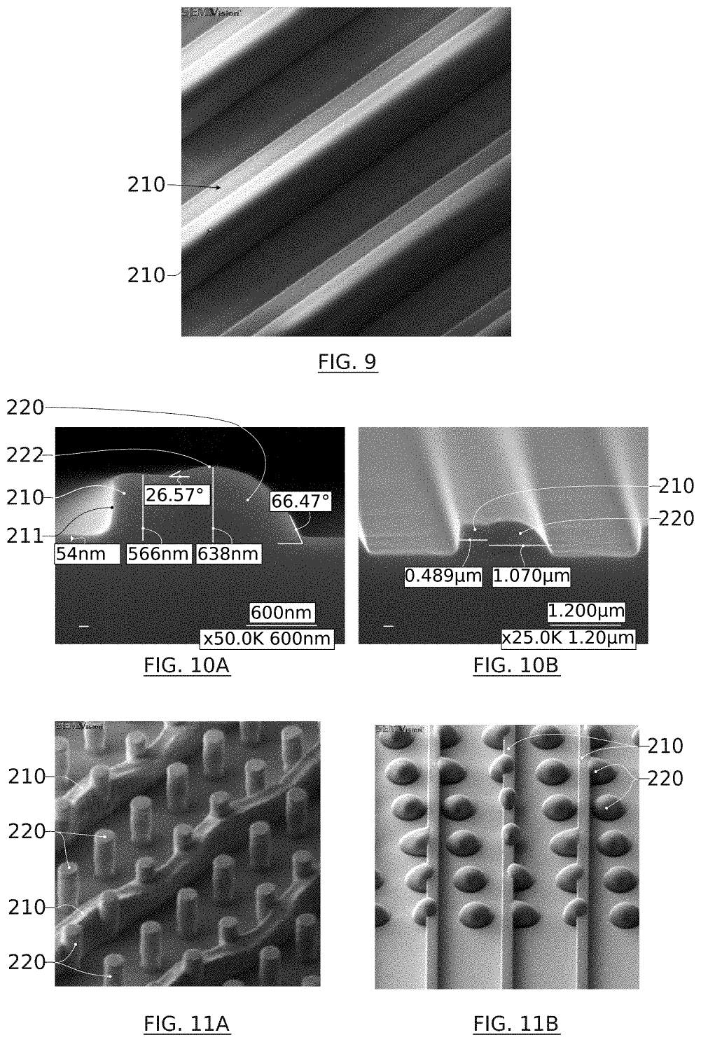

FIG. 9 is a perspective photo illustrating an example of a network of line structures that could be obtained with the method according to the invention.

Each structure of this network has a pattern 210, extending longitudinally, stabilised and insensitive to creeping and a pattern 220, contiguous to the patterns 210 and also extending longitudinally, which is sensitive to creeping. This network is obtained with the resin M78Y.

FIGS. 10A and 10B are sectional photos, with decreasing magnifications, of one of the structures of the network shown in FIG. 9.

In these sectional photos, one could clearly notice that no discontinuity is observed between the stabilised pattern 210 before creeping and the creep-sensitive pattern 220. Thus, the structure features a perfect material homogeneity. As indicated hereinabove, this is particularly advantageous for the subsequent steps of the method, in particular during the etching steps which will allow replicating the structure in a functional layer in a perfectly faithful manner.

In this example, during the creeping step, the structure has been brought to a temperature of 175° for a period of 15 minutes.

In the example illustrated in the photo of FIG. 11A, the stabilised patterns 210 form lines and are carried out at first. Hence, these lines are insensitive to creeping at the temperature Tfluage of the resin.

Afterwards, the patterns 220 are made and form positive resin plots. These plots are positioned at variable distances from the lines.

FIG. 11B is a photo showing the structure upon completion of the creeping step. One could notice that it is possible to make structures with sidewalls having different slopes when the patterns 220 that creep are backed up against the stabilised resin line. For the other patterns 220, one could notice that the crept shape is symmetrical around an axis of revolution of the plot. Thus, with similar patterns 210, 220 and with a similar creeping step, slopes with a different inclination will be obtained depending on the proximity between the patterns 210 and 220.

In this example, creeping is carried out at a temperature of 175° C. for 15 minutes.

In the non-limiting examples described hereinabove, the stabilised patterns 210 have vertical sidewalls (inclination α211 forming a right angle with the face 101 of the substrate 100).

However, the invention is not limited to structures having this inclination for the sidewalls of the stabilised patterns 210.

Indeed, the invention allows obtaining a structure having asymmetrical sidewalls, i.e. sidewalls with different inclinations, yet without these sidewalls being vertical.

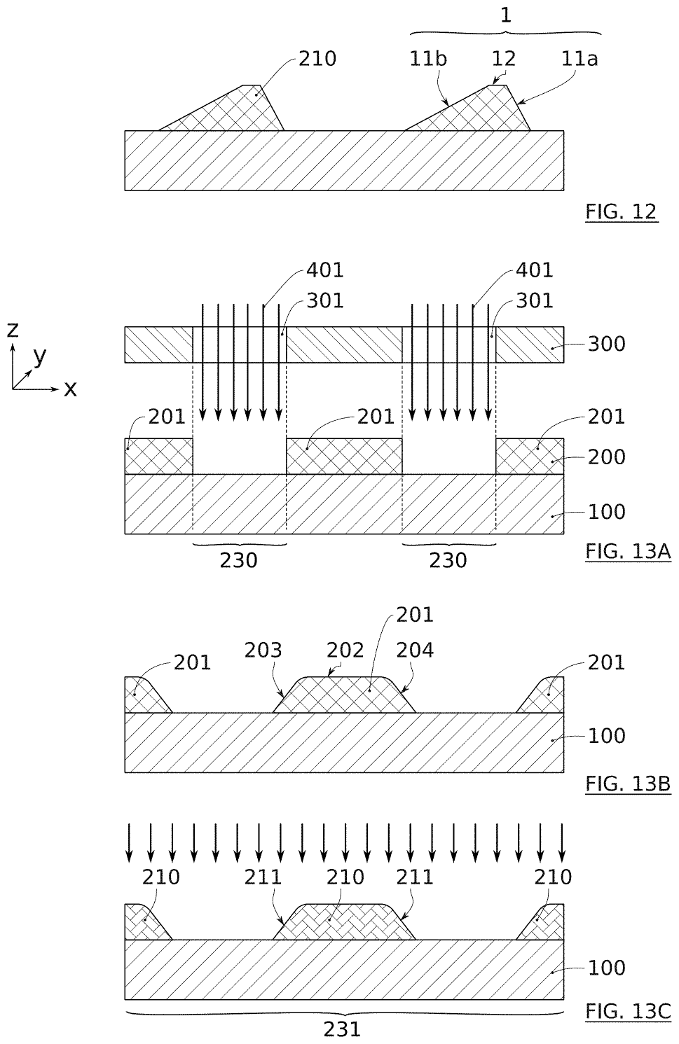

FIG. 12 schematically illustrates such a structure 1, having a top 12, sidewalls 11a having a first inclination and sidewalls 11b having a second inclination different from the first inclination.

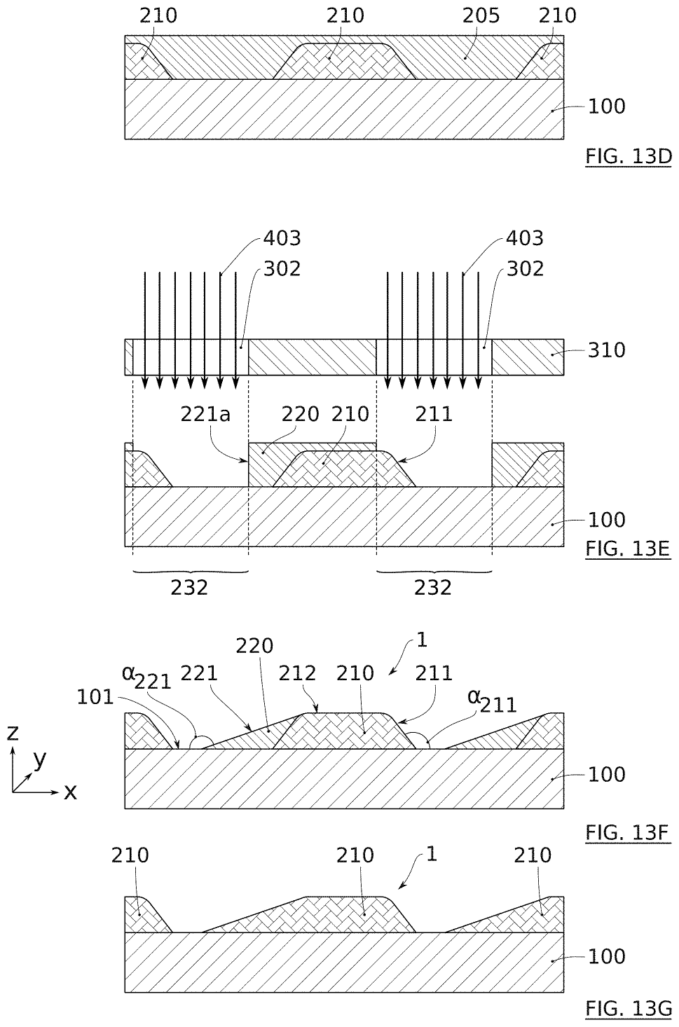

FIGS. 13A to 13G schematically illustrate steps of an embodiment allowing obtaining a structure with non-vertical inclined sidewalls such as that illustrated in FIG. 12.

As illustrated in FIG. 13A, a first step consists in exposing 401 the positive resin layer 200 through a mask 300. The openings 301 of the mask 300 allow exposing areas 230 by applying thereto a dose called prior dose Dp. Dp is such that Dactivation≤Dp≤Dinversion. Afterwards, the positive resin is developed (non-illustrated step), i.e., the exposed areas 230 are dissolved. The non-exposed positive resin portions remain in place. These portions form the prior patterns 201. These prior patterns 201 could be binary patterns, depending on the homogeneity of the thickness of the initial layer 200 and the openings of the mask.

Afterwards, a creeping step is performed. The prior patterns 201, sensitive to creeping, deform and have their sidewalls 203, 204 rounded or tilted. If these prior patterns 201 do not encounter other patterns, in particular stabilised patterns, their sidewalls 203, 204 have identical inclinations. The result of the creeping step is illustrated in FIG. 13B.

FIG. 13C illustrates a next step of exposing the prior patterns 201. The dose D1 applied to these patterns is higher than Dinversion. Thus, these prior patterns 201 stabilise and become insensitive to creeping. These stabilised patterns and their sidewalls are respectively referenced 210 and 211. Preferably, this exposure is carried out full plate.

FIG. 13D illustrates the deposition of an additional resin layer 205. Advantageously, this resin layer 205 is identical, i.e. it has the same chemical composition as the layer 200. Hence, it consists of resin having a positive tone once deposited over the substrate 100. Preferably, this layer 205 entirely covers the stabilised patterns 210. Also preferably, this layer 205 is not congruent and has a planar upper face parallel to the face 101 of the substrate 100.

As illustrated in FIG. 13E, it is then proceeded with a lithography step to define in the layer 205 patterns 220 formed by a positive resin.

For this purpose, it is possible to use a mask 310 different from the mask 300 used beforehand. It is also possible to use the same mask 300 to which an offset with respect to the position of the first lithography will be applied.

During this lithography step, the exposure 403 brings in a dose to areas 232 of the layer 205. This dose D2 is higher than or equal to Dactivation and is lower than Dinversion.

During this exposure step 403, the stabilised patterns 210 could receive all or part of the dose D2. This will not affect them.

Thus, after a development step (not illustrated), the portions of the layer 205 located in the areas 232 are dissolved. Preferably, the pattern 220 formed by the positive resin remains in place and covers at least one sidewall of the stabilised pattern 210. This pattern 220 also covers at least one portion of the top 212 of the stabilised pattern 210.

The step illustrated in FIG. 13F illustrates a creeping step enabling the creep-sensitive pattern 220 to deform. This pattern 220 covers at least one portion of some sidewalls 211 of the pattern 210 by forming an inclination α221. The pattern 210 keeps a sidewall 211 at least partially cleared and having an inclination α211 different from the inclination α221.

As described in the previous embodiments, optionally, a stabilising step is performed consisting in imparting on the entire structure 1a dose higher than or equal to Dinversion. This step is illustrated in FIG. 13G. It allows making the patterns 220 having crept before insensitive to creeping. This step also allows conferring a perfect homogeneity on the structure 1, that being so in particular in order to facilitate the subsequent steps of transferring the structure 1 into another substrate.

The invention is not limited to the previously-described embodiments and extends to all embodiments covered by the claims.

For example, the illustrated examples, except the embodiment illustrated in FIG. 5, describe that only the resin areas located in line with the openings of the masks are exposed and receive a dose. Naturally, these embodiments are perfectly compatible with masks that lead, often intentionally, to an area peripheral to that located directly in line with an opening receiving a given dose. If this dose applied at the peripheral area is

lower than the dose Dactivation, then the described methods and in particular those illustrated in FIGS. 3, 4 and 13 directly apply.

higher than Dactivation, then the method described in FIG. 5 could apply.

In the above-described embodiments, the first patterns exposed to a first dose D1≥Dinversion as well as the second patterns exposed to a second dose D2<Dinversion extend from the same face of the substrate or from the same layer. Preferably, these first and second patterns are in contact with the substrate or with this layer. According to an alternative embodiment, it is possible to provide for the second patterns not extending from the substrate. These second patterns could be partially or entirely supported by the first patterns while leaving a portion of the sidewalls of the first patterns bare. Thus, a stack having first patterns topped by second patterns is defined. The first patterns have first sidewalls having an inclination α211 with respect to said plane (XY). The second patterns, located over the first patterns, will creep more than the first patterns. After creeping, these second patterns have second sidewalls whose inclination α221 with respect to said plane (XY) is different from α211.

1-17. (canceled)

18. A method for making at least one structure comprising sidewalls having different inclinations, with respect to a plane in which primarily extends a face of a substrate on which rests the structure, comprising:
providing a stack comprising a substrate topped by at least one layer of a photosensitive or electro-sensitive resin, the resin being such that:
when the resin is exposed to an insolation dose D<Dinversion, the resin has a positive resin behaviour and creeps when it is subjected to a temperature T higher than or equal to a glass-transition temperature Tcreep, and
when the resin is exposed to an insolation dose D≥Dinversion, the resin has a negative resin behaviour and does not creep at a temperature T≥Tcreep,
forming at least one first pattern by exposure of at least one first area of the resin to a first dose D1≥Dinversion, the first area defining for the structure the first pattern, the first pattern having a contour comprising at least one first sidewall, the first sidewall having a first inclination with respect to said plane,
before or after formation of the first pattern, forming at least one second pattern by exposure of at least one second area of the resin, the second area being at least partially different from the first area, to a second dose D2<Dinversion, and then developing the second area so as to leave in place, outside the second area, resin defining the at least one second pattern,
performing creeping by applying to the stack a temperature T≥Tcreep for a controlled duration, so as to make the second pattern creep without making the first pattern creep, until the second pattern creeps over at least one portion of the first pattern by:
leaving uncovered at least partially the first sidewall of the first pattern having said first inclination, and
defining at least one second sidewall for the structure, the second sidewall having with respect to said plane a second inclination different from the first inclination.

19. The method according to claim 18, wherein forming the second pattern is performed after the step of forming the first pattern.

20. The method according to claim 18, wherein, forming the at least one first pattern and forming the at least one second pattern are performed in a same lithography equipment and without removing the stack from the equipment between the two forming operations.

21. The method according to claim 18, wherein forming the first pattern and forming the second pattern are performed so that before the creeping the second pattern is in contact with the first pattern.

22. The method according to claim 18, comprising, after forming the first pattern and before forming the second pattern, depositing an additional layer made of the resin, the second area exposed to form the second pattern being embedded in the additional layer and the second pattern being formed in said additional layer.

23. The method according to claim 22, wherein, before creeping the second pattern covers a top of the first pattern and at least one portion of a height of a portion of the contour of the first pattern, the height being considered according to a direction normal to a plane in which primarily extends a face of the substrate on which rests the layer of the resin.

24. The method according to claim 18, wherein forming the first pattern and forming the second pattern are performed so that before creeping the second pattern, the second pattern is in contact with at least one portion of the contour of the first pattern without covering a top of the first pattern.

25. The method according to claim 18, wherein during forming the first pattern, the exposure of the at least one first area to the dose D1 simultaneously exposes, at a periphery of the first area, a portion of the second area with a dose higher than or equal to Dactivation and lower than Dinversion, so that before the creeping the second pattern is at a distance from the first pattern.

26. The method according to claim 25, wherein dimensions of the second pattern and creep conditions are set so that at an end of the creeping the second pattern is in contact with the first pattern.

27. The method according to claim 18, wherein the inclination of the first sidewall of the first pattern forms a right angle with the plane in which extends the face of the substrate.

28. The method according to claim 18, wherein, before forming the at least one first pattern, the method comprises:
forming at least one prior pattern by exposing at least one prior area of the resin to a dose Dp≤Dinversion and then developing the at least one prior area so as to leave the at least one prior pattern in place, and
creeping the at least one prior pattern so that the prior pattern comprises at least one sidewall having the first inclination and configured to form the first sidewall, the exposure of at least one first area of the resin to a first dose D1≥Dinversion is applied to the prior pattern, so as to define the first pattern whose first sidewall has the first inclination.

29. The method according to claim 28, wherein the inclination of the first sidewall of the first pattern forms an angle with the plane in a range between 90° and 180°.

30. The method according to claim 29, wherein the angle is in a range from 95° to 175°.

31. The method according to claim 28, comprising, after forming the first and before forming the second pattern, depositing an additional layer of the resin, the second area exposed to define the second pattern being embedded in the additional layer and the second pattern being formed in the additional layer.

32. The method according to claim 18, wherein forming the first pattern, forming the second pattern and creeping are performed so that at an end of the creeping a top of the first pattern is in contact with a top of the second pattern.

33. The method according to claim 18, comprising, after creeping, a step of exposing at least the second pattern to an insolation dose Df≥Dinversion.

34. The method according to claim 18, wherein the first pattern and the second pattern rest on a same layer while being in contact with the same layer.

35. The method according to claim 22, wherein, before creeping the second pattern covers a top of the first pattern and a height of a portion of the contour of the first pattern, the height being considered according to a direction normal to a plane in which primarily extends the face of the substrate on which rests the layer of resin.

36. A structure made of a photosensitive or electro-sensitive resin and having:
at least one first sidewall having a first inclination with respect to a plane in which primarily extends a face of a substrate on which rests the structure, and
at least one second sidewall having a second inclination different from the first inclination,
wherein the first sidewall consists of a portion of said resin having a negative resin behaviour and the second sidewall consists of a portion of said resin having a positive resin behaviour, portions of said resin forming the first sidewall and the second sidewall having a same chemical composition, and
wherein the resin portions forming the first sidewall and the second sidewall are in contact.
